(19) United States
(12) Patent Application Publication
(10) Pub. No.: US 2013/0255755 A1
(43) Pub. Date: Oct. 3, 2013

(54) Solar Roof Shingles and Underlayment with Wireless Power Transfer and Related Components and Systems

(71) Applicant: BUILDING MATERIALS INVESTMENT CORPORATION, Dallas, TX (US)

(72) Inventor: Adem Chich, Kearny, NJ (US)

(73) Assignee: Building Materials Investment Corporation, Dallas, TX (US)

(21) Appl. No.: 13/847,028

(22) Filed: Mar. 19, 2013

Related U.S. Application Data
(60) Provisional application No. 61/617,969, filed on Mar. 30, 2012.

(51) Int. Cl. H01L 31/042; H01L 31/048

(52) U.S. Cl. CPC H01L 31/0428; H01L 31/0482
USPC 136/251; 52/173.3

(57) ABSTRACT

A system of solar roof shingles and underlayment with wireless power transfer between the solar roof shingles and the underlayment is disclosed. Each solar roof shingle has a solar collector array coupled to a wireless resonator. The solar collector array establishes a voltage in response to exposure to sunlight and the wireless resonator converts the voltage to a transmittable electromagnetic signal. The signal is transmitted to resonant devices embedded in the underlayment beneath the shingles. The resonant devices may be resonant capture devices that convert the received electromagnetic signal back to a usable voltage, or they may be wireless repeaters that retransmit the electromagnetic signal to remote resonant capture devices, which then convert it to a voltage. This voltage is placed on an electrical grid and made available at a remote location for use, storage, or placement on the public electrical grid. Various components and systems that support or enhance the basic system are disclosed.

### REFERENCE TO RELATED APPLICATION

Priority is hereby claimed to the filing date of U.S. provisional patent application 61/617,969 filed on Mar. 30, 2012.

### TECHNICAL FIELD

This disclosure relates generally to solar power and more specifically to solar shingles for shingling the roof of a structure and to the transfer of electrical power from the solar shingles to an electrical grid. The disclosure also relates to components and systems for use with wireless power transfer in a photovoltaic array.

### BACKGROUND

Solar panels installable on the roof of a home have been available for many years. In the past, these panels tended to be large and thick and were mounted above the traditional shingles of the roof on support structures. Such installations, while indeed contributing to a reduction in domestic electricity bills, were nevertheless considered by some to be unsightly and for this and other reasons, enjoyed limited success and acceptance, particularly in residential applications. Further, installation of such solar panels required specialized installers and substantial electrical expertise to wire the panels together into an electrical grid and to couple them to the home and to the public electrical service.

More recently, solar shingles have been developed as an alternative to roof mounted solar panels. These solar shingles are relatively thin, flexible, and mount to a roof in substantially the same way as traditional shingles. Therefore, they can be installed for the most part by roofing contractors. However, the shingles must still be electrically connected together by wires and connectors into an electrical grid that, in turn, delivers power ultimately to a home's electrical system through an inverter or inverters or other equipment. While solar shingles such as these represent an improvement over old roof mounted solar panels for domestic use, they nevertheless still require interconnection with a grid of wires. The interconnection itself can be quite complicated, requiring the services of skilled electricians. Furthermore, the wires and connectors used to interconnect the solar shingles can become unreliable or disconnected over time resulting in outages or efficiency reduction of the system as a whole.

Transferring electrical power generated by solar shingles without wired connections has been suggested. U.S. Pat. No. 8,035,255 of Kurs et al., for example, suggests the use of a disclosed wireless coupled resonator power transfer technology for this purpose. However, this references teaches that resonant capture resonator devices that couple with source resonators on the solar shingles be mounted inside the building beneath the roof. This approach would be labor intensive and would require specialized expertise and very precise location schemes to align the resonant capture devices in the attic with solar shingles on top of a roof, which are not visible from the attic. Repair or replacement of components also would be cumbersome and time consuming with such a solution. The Kurs et al. patent mentioned above is hereby incorporated fully by reference for its teaching of a wireless coupled resonator power transfer technology useful in the present invention.

A need therefore exists for a system and methodology for capturing electrical power generated by solar shingles and other solar panels that does not require that the shingles be interconnected in a wired electrical grid, that is installable by a roofing contractor without the requirement of special expertise, and that does not result in arrays of electrical equipment located in the attic space of a home. A further need exists for components and systems that relate to, improve, and support the core technology. It is to the provision of a system and methodology and supporting components and systems that addresses this and other needs that the present invention is primarily directed.

### SUMMARY

Briefly described, a solar shingle system includes, in one embodiment, an array of solar shingles mountable on the roof of a home or other structure. The solar shingles are installable by a traditional roofing contractor and may be generally configured similarly to any of a number of commercially available solar shingles. Unlike commercially available shingles, however, each shingle of the present invention is provided with a wireless resonator and may (or may not) also include a micro-inverter to convert the DC voltage established by the solar shingle to AC voltage.

An underlayment and underlayment structures are disclosed for installation by the roofing contractor on a roof deck beneath where the solar shingles are to be installed. The underlayment and underlayment structures such as insulation (collectively referred to herein as merely “underlayment”) provides a traditional foundation, insulation, and protection for overlying shingles, and water proofing for an underlying roof deck, but also includes an array of resonant capture devices. The resonant capture devices may be arrayed to correspond to the arrangement of solar shingles to be installed atop the underlayment. Solar shingles are installed atop the underlayment with the resonators of the shingles aligned in a predetermined relationship relative to the resonant capture devices in the underlayment. Thus, electrical power generated by the solar shingles is transferred wirelessly to the resonant capture devices within the underlayment.

In one embodiment, the underlayment is formed with an integrated wired grid that couples the resonant capture devices within the underlayment together and delivers electrical power they generate to a central location for use, storage, or transmission. In another embodiment, wireless repeaters may be incorporated into the underlayment with the repeaters forming a wireless network for transferring power to one or more remotely located resonant capture devices. This embodiment avoids the wired grid within the underlayment. In another embodiment, the resonant capture devices are incorporated into fasteners used to fasten the shingles to the roof. In this embodiment, the fasteners make electrical connection to a wiring grid in the underlayment when installed. In yet another embodiment, resonant capture devices or wireless repeaters are incorporated into an insulation layer beneath a membrane on which shingles are installed. These and addition components and systems are disclosed in more detail below.

It will thus be seen that an improved solar shingle system is disclosed that is significantly less complicated to install, does not require that a roofer connect a wiring grid to the shingles during installation, does not result in equipment inside the attic of a dwelling, and that generally requires only the skills of a traditional roofer. These and other features and advantages of the disclosed system and methodology will be better appreciated upon review of the detailed description presented below taken in conjunction with the accompanying drawing figures, which are briefly described as follows.

### BRIEF DESCRIPTION OF THE DRAWINGS

FIG. 1 is a perspective simplified view of a dwelling being provided with solar shingles and underlayment according one embodiment of the present disclosure.

FIG. 2 is a side elevational view with dimensions exaggerated for clarity showing the underlayment with embedded resonant capture devices and/or wireless repeaters and a solar shingle having a wireless resonator and optional micro-inverter.

FIG. 3 is a schematic diagram illustrating one embodiment of interconnection relationships between the various components of the system of this disclosure.

FIG. 4 is a schematic diagram illustrating an alternate embodiment of interconnection relationship between the various components in the depicted alternate embodiment.

### DETAILED DESCRIPTION

Reference will now be made to the annexed drawing figures briefly described above. It should be appreciated that these figures are intended to be generic and may be simplified to illustrate only exemplary embodiments of the present invention. Further, dimensions and relationships of features in the drawings may be exaggerated for clarity.

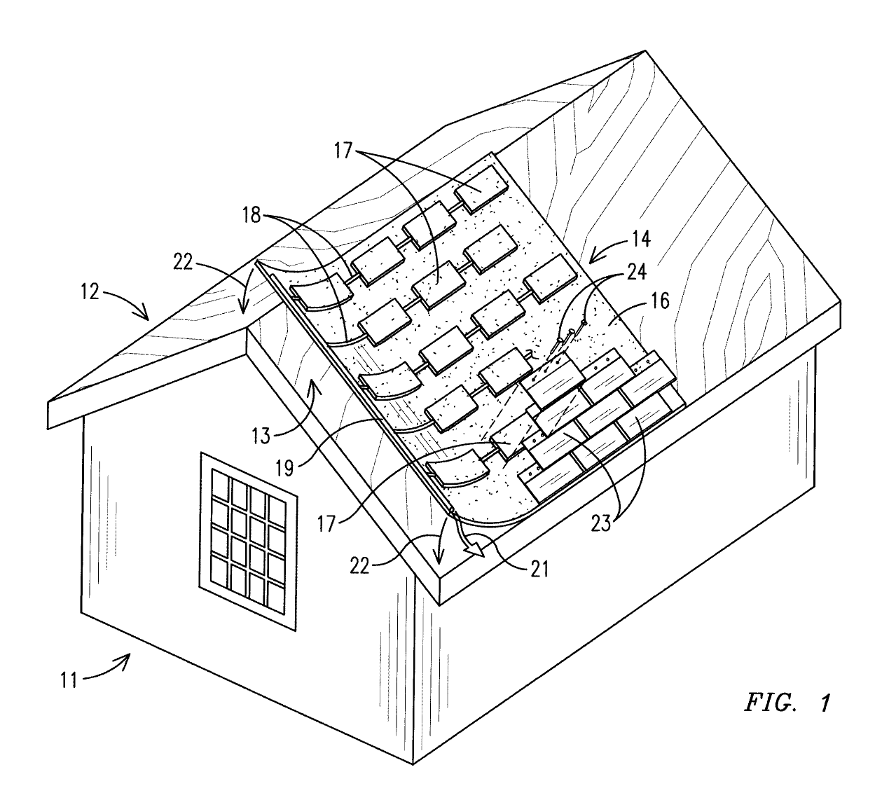

FIG. 1 shows a dwelling 11 having a roof 12 with a roof deck 13. The roof deck may be plywood or pressboard covering and secured to roof rafters in the attic space below. The dwelling 11 is intended to be provided with a solar power collection system covering at least a portion of the roof deck to collect solar radiation and convert the radiation to electrical power. To this end, an underlayment according to one aspect of the invention is shown being laid atop the roof deck in the region to receive solar shingles. The underlayment is shown as a single membrane in FIG. 1, but it may be installed from rolls of substantially less width with upper sheets of the membrane of the underlayment overlapping lower sheets. In this sense, the underlayment can be installed in a manner similar to traditional felt, polymer sheet, and other roofing underlayment materials and thus can be installed by general roofing contractors. Further, as detailed below, an insulation system such as spray foam or insulation boards may be installed beneath the membrane.

The underlayment of this embodiment includes an array of resonant capture devices 17. The resonant capture devices may be embedded within the material of the underlayment, sandwiched between two layers of sheet material, or affixed to the underside of the underlayment so that they are protected from the elements and maintained in a properly spaced array on the roof by the underlayment. In another embodiment, detailed below, capture devices may be incorporated into an insulation layer beneath a membrane. Electrical wiring 18 may couple the resonant capture devices together and to an electrical bus 19, which also may be embedded within the material of the underlayment for similar purposes. In an embodiment described below, wireless repeaters instead of resonant capture devices are integral to the underlayment and in such an embodiment, a wired grid may not be required. The membrane of the underlayment may be made of a variety of materials including, for example, TPO, polyolefins, PET, EDPM, asphalt, saturated glass mat, or cellulosic felt paper or a combination of these. When installed on a roof, the underlayment establishes a spaced apart array of resonant capture devices (or wireless repeaters). These resonant capture devices may be similar in operation to the devices disclosed in the incorporated patent of Kurs et al. or an equivalent technology. The details of these devices and their operation thus need not be described in great detail here.

In the illustrated embodiment, the resonant capture devices are shown electrically connected together and each row of capture devices is electrically connected to and electrical bus 19. The resonant capture devices may be wired in any suitable configuration such as, for example, in series, in parallel, or combinations thereof according to application specific parameters and/or the desired net voltage to be developed. The electrical voltage established by the resonant capture devices is applied to a wiring bus 19, which, in turn, directs it to a remote location for use, storage, or to be placed back on the public electrical grid.

In an alternate embodiment, the resonant capture devices in the underlayment are replaced with wireless repeaters. Such wireless repeaters are disclosed in the incorporated Kurs et al. patent and thus need not be described in detail here. Generally, however, such repeaters are resonantly tuned to wireless resonators but, instead of capturing electrical power from adjacent wireless resonators, repeaters act rather like a relay that re-transmits the received power wirelessly to one or more remotely located resonant capture devices. Thus, a wired electrical grid within the underlayment may not be required in this alternate embodiment. Further, the use of wireless repeaters may be economically more desirable than embedding multiple resonant capture devices and a wired grid within the underlayment. An array of wireless repeaters also allows for “voltage hopping” to and/or between resonant capture devices and, significantly, may allow for “network monitoring;” that is, being able to identify through monitoring in or associated with the resonant capture devices voltages being transferred by the individual repeaters. In this way, a potential underperforming and/or bad solar shingle or its wireless resonator may be localized so that it can be repaired or replaced as a regular maintenance activity.

With continued reference to FIG. 1, number of solar shingles 23 are shown installed and being installed atop the underlayment. These shingles may take on virtually any configuration; however, in the illustrated embodiment they are configured and installed generally as are solar shingles that are currently commercially available. These solar shingles are laid in courses in the same manner as traditional shingles and attached to the roof deck with nails 24 that are driven through the hidden flap of each shingle, through the underlayment, and into the roof deck. As illustrated in FIG. 1, the shingles 23 are installed in a predetermined aligned relationship with corresponding resonant capture devices 17 (or wireless repeaters) of the underlayment below. In the illustrated embodiment, each shingle 23 is aligned with a corresponding resonant capture device 17. However, other embodiments are possible wherein, for example, one resonant capture device might receive signals from two or more solar shingles so that configurations different from the one-to-one relationships shown in FIG. 1 are contemplated and within the scope of the invention. Where wireless repeaters are employed, one remotely located resonant capture device may receive power from several wireless repeaters thereby simplifying the system.

As discussed in more detail below, each solar shingle is provided with a wireless resonator according to the incorporated Kurs et al. patent, or an equivalent technology, capable of transmitting electrical power wirelessly from the solar shingle to a corresponding resonant capture device or a corresponding wireless repeater device. Generally, this is accomplished by converting the voltage established by the solar shingles to a transmittable electromagnetic signal and transmitting this signal to a resonant capture device or a repeater that is resonantly tuned to the wireless resonator. In this way, power transfer is highly efficient.

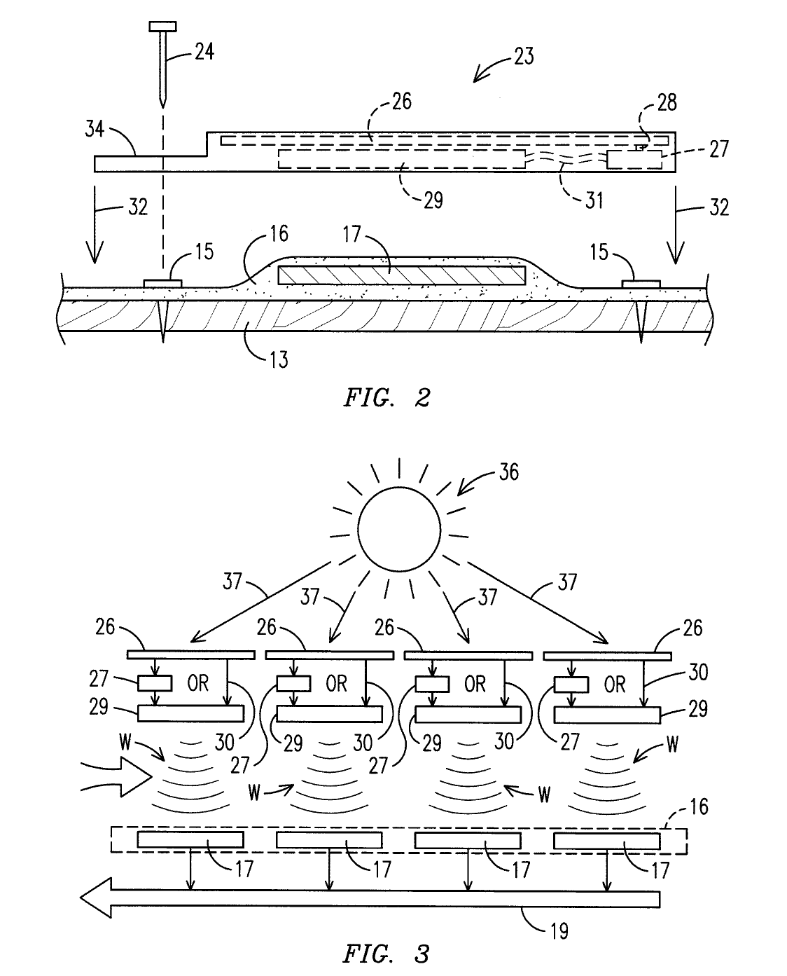

FIG. 2 illustrates in more detail one possible embodiment of an underlayment and solar shingle according to this disclosure. Relative dimensions and sizes may be exaggerated in FIG. 2 for clarity and ease of understanding. Further, the underlayment is described within the context of the embodiment wherein resonant capture devices are incorporated into the underlayment. However, the description applies generally to wireless repeaters rather than resonant capture devices in the underlayment.

The underlayment 16, in the form of a membrane in this case, is shown attached to the roof deck 13 with nails 15 or other appropriate fasteners. A resonant capture device 17 is illustrated in this embodiment as being embedded within the material of the underlayment as described above. The capture device also may be otherwise captured in the material of the underlayment if desired or affixed to the underside of the material of the underlayment, or incorporated into an insulation layer beneath the membrane. Regardless, the underlayment protects the resonant capture device and positions an array of devices in a properly spaced and positioned array on the roof deck.

A solar shingle 23 is configured to be attached atop the roof covering a section of the underlayment 16. In this example, the solar shingle 23 is attached in a manner similar to standard shingles with nails 24 extending through a nailing flange 34, through the underlayment 16, and into the roof deck 13. Other solar shingle configurations and attachment techniques are available and/or possible and should be considered to be within the scope of the present invention. In general, however, the solar shingle 23 comprises a solar cell array 26 that is exposed to sunlight to establish an electrical voltage when the solar shingle is installed on the roof and illuminated. A wireless resonator 29 is mounted within the solar shingle 23 and is located to align in a predetermined relationship with a corresponding resonant capture device 17 of the underlayment below when the solar shingle is attached to the roof. In the illustrated embodiment, the wireless resonator 29 aligns in an overlying relationship with the resonant capture device. Such a relationship is not, however, a limitation of the invention and other alignment relationships may well be designed by the skilled artisan.

In the illustrated embodiment, the solar shingle also includes a micro-inverter 27 that is coupled to the DC voltage produced by the solar cell array 26, converts this DC voltage to an AC voltage, and directs the AC voltage to the wireless resonator 29. While this is one possible arrangement, it should be understood that the micro-inverter may be eliminated from each shingle with the voltage inversion being accomplished by a larger inverter in a location remote from the individual shingles. Micro-inversion at each shingle may be preferred in some situations because of cost, space, and efficiency considerations.

When the solar shingle 23 is installed and exposed to sunlight, the solar cell array produces a DC voltage. This voltage, which may be inverted to AC voltage, is delivered to the wireless resonator 29, converted to a transmittable electromagnetic signal, and transmitted wirelessly thereby to the resonant capture device 17. The resonant capture device converts the received electromagnetic signal back to electrical energy. The wiring grid within or associated with the underlayment in this embodiment interconnects the resonant capture devices 17 together electrically and delivers the electrical energy produced by all of them to a remote location. There, the electrical energy may be used to power household appliances, or may be stored in a battery bank or placed on the public electrical grid as desired.

As described above, the resonant capture devices as illustrated in FIG. 2 may be replaced with wireless repeaters. In such an embodiment, each wireless repeater receives energy transmitted by a wireless resonator associated with a solar shingle and re-transmits the received energy wirelessly to one or more resonant capture devices, which may be remotely located. Such an embodiment may provide certain advantages including reduced cost, elimination of a wired grid in the underlayment, system monitoring capabilities, and others as described in more detail above.

FIG. 3 is a schematic illustration showing one embodiment of how the system of this invention might function in the field. The solar cell arrays 26 of the solar shingles are exposed to solar radiation 37 from the sun 36. In response, the solar cell arrays 26 generate or establish a DC voltage. This DC voltage can be converted to a corresponding AC voltage if desired using micro-inverters 27 located on each solar shingle or servicing two or more solar shingles. This AC voltage can then be coupled to the wireless resonator 29 of the solar shingle. Alternatively, the DC voltage produced by the solar cell array 26 can be coupled directly to the wireless resonator 29 without being inverted by an inverter.

In response to a voltage from the solar cell array, the wireless resonator functions as described in detail in the incorporated Kurs et al. patent to convert the voltage to a transmittable electromagnetic signal W, which, in turn, is transmitted without a physical connection to and received by the corresponding resonant capture device 17. The resonant capture device 17, then, converts the wireless electromagnetic signal back to a usable voltage, which is added to the voltages generated by other resonant capture devices through an electrical grid 19. The voltage is then available on the grid to power appliances, to be stored, or to be placed on the public electric grid as desired.

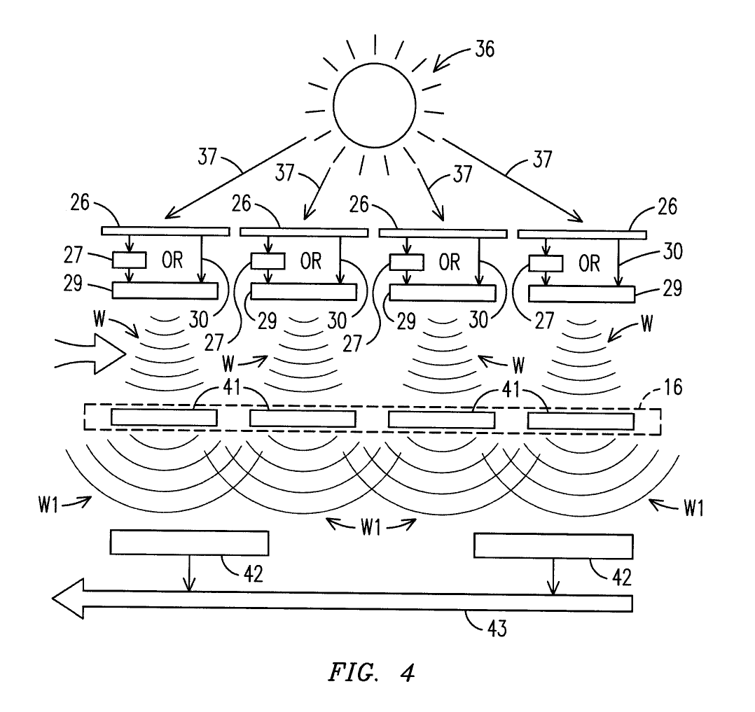

FIG. 4 is a schematic illustration of the embodiment of this invention wherein wireless repeaters rather than resonant capture devices are embedded within or otherwise associated with the underlayment. As with the embodiment described above, the solar cell arrays 26 of the solar shingles are exposed to solar radiation 37 from the sun 36. In response, the solar cell arrays 26 generate or establish a DC voltage. This DC voltage can be converted to a corresponding AC voltage if desired using micro-inverters 27 located on each solar shingle or servicing two or more solar shingles. This AC voltage can then be coupled to the wireless resonator 29 of the solar shingle. Alternatively, the DC voltage produced by the solar cell array 26 can be coupled directly to the wireless resonator 29 without being inverted by an inverter.

In response to a voltage from the solar cell array, the wireless resonator functions as described in detail in the incorporated Kurs et al. patent to convert the voltage to a transmittable electromagnetic signal W, which, in turn, is transmitted without a physical connection to an array of wireless repeaters 41 embedded or otherwise incorporated into an underlayment 16. The wireless repeaters 41 then function as wireless relays that re-transmit wireless power W1 to one or more remotely located resonant capture devices 42. The capture devices capture and convert the received wireless power W1 back to a usable voltage and are connected to an electrical grid 43. The voltage is then available on the grid to power appliances, to be stored, or to be placed on the public electric grid as desired. In this embodiment, the wireless repeaters also may each transmit a unique identifier to the resonant capture devices. The capture devices can then be configured to monitor power received from each wireless repeater. In the event a repeater stops transmitting or transmits weak signals, then the resonant capture device or devices can identify a problem in the system and notify individuals for inspection and/or repair.

Having described and illustrated the basic invention above, a variety of components and component systems that may be useful with or that may enhance the basic invention will now be described in the following headed paragraphs.

Wireless Resonator Integration

In a system such as that described above, wireless resonators may be integrated into solar shingles in a variety of ways. Traditionally, such shingles are provided with a hermetically sealed junction box on the back of the shingle substrate through which wires of an electrical grid are connected to the solar cell array of the shingle. With the present invention, wired interconnection of solar shingles is eliminated, and so there is no need for the junction box. Accordingly, one aspect of the invention is that the traditional hermetically sealed junction box is eliminated and replaced by a wireless resonator as described above. This simplifies the solar shingle in many ways including, for example, the elimination of potting to seal the junction box, the complete elimination of the need for a hermetic seal, and the elimination of a component that generally is sufficiently large and heavy that extra support structure is required in the shingle substrate to support the junction box. This can result in a thicker than perhaps desirable solar shingle. Further, because of its size, the junction box generally is located on the back of the shingle substrate making interconnection and installation difficult for a roofer and making it more difficult to access in the event a repair or replacement is needed.

Since wireless resonators are thin and light by comparison to traditional wired junction boxes, they can be located substantially anywhere on the solar panel such as, for example, on or along the edge of a shingle. In addition, once mounted, they are much more closely in the plane of the solar cell array. As a result, support structure can be reduced or eliminated, the shingle can be made thinner and lighter, and the shingle is simpler to install and repair. As mentioned, the electrical energy produced by the solar cell array can be converted to AC or left as a DC voltage and either transmitted through the wireless resonator to resonant capture devices interconnected to aggregate power to supply to the grid or to an external load. Advantages of this aspect of the invention include the elimination of arcing and shorting risks present with traditional wired solar shingles, a reduction of the labor required for installation, and the elimination of any special skills needed to install the solar shingles. Typical roofing practices are employed for installation.

Fasteners as Capture Resonators or Repeaters

Mechanical fasteners such as nails, screws, rivets, washers, or bolts are used to attach an insulation layer such as insulation boards to the deck of a roof in a commercial roofing installation. The insulation layer is then covered with a waterproof membrane in known ways. Fasteners also are used to attach shingles to a roof over an underlayment in residential applications. In either case (commercial roofing membranes or shingles) solar collectors can be incorporated into the membrane or shingle to be exposed to sunlight and wireless resonators can be associated with the collectors as described above. Also as discussed, wiring grids can be incorporated into the underlayment beneath the roofing membrane or shingles. In one aspect of the invention applicable to residential roofing, resonant capture devices or wireless repeaters are incorporated into a fastener itself and the fastener, when installed, couples the resonator or repeater to an electrical grid below to supply the grid or to supply an external load. For example, a unique fastener that incorporates a resonant capture device is used as one of the fasteners with which a solar shingle is attached to a roof atop an underlayment. The solar array of the shingle is coupled to a wireless resonator on the shingle as described above and the underlayment below may incorporate a wire network or an induction coupled circuit for aggregating power to supply the grid or an external load.

As the unique fastener of this aspect is installed through the nailing flange of a solar shingle, through the underlayment, and into a roof deck, it may make electrical contact with the wire network incorporated into the underlayment. Alternatively, it may position the resonant capture device or wireless repeater incorporated into the fastener in proper alignment with an induction node within an induction coupled circuit incorporated into the underlayment. In either case, when the illuminated solar array of the shingle induces an electrical voltage, the voltage is converted to a transmittable electromagnetic signal and transmitted by the wireless resonator of the shingle. The signal, in turn, is received by the resonant capture device or the wireless repeater incorporated into the special fastener securing the shingle to the roof. In the case of a resonant capture device, the received signal is converted back to a usable voltage by the resonant capture device. This voltage may then be coupled to a wire network in the underlayment through direct electrical contact between the fastener and the wire network. Alternatively, it may be coupled through induction in the case of an induction coupled circuit in the underlayment.

Advantages of incorporating elements of a wireless power transfer system into fasteners include simplifying installation since a roofer simply fastens shingles in the traditional way using the special fasteners, and all appropriate alignments and connections are made automatically. There are no wires to connect, no risk of arcing or shorting, and a lower level of skill is required to install a system properly.

Components in an Insulation Layer

Some roofing installations, including most commercial roofing installations and many residential roofing installations, include shingles or an impervious membrane applied over an insulation layer comprising insulation board or spray foam insulation, an underlayment, and a structural deck. In one aspect of the present invention, the singles or impervious membrane of such a roofing installation incorporates photovoltaic solar cells on its exposed surface and corresponding wireless resonators on its bottom surface facing the insulation layer. Resonant capture devices and/or wireless repeaters may then be embedded or otherwise incorporated into the insulation layer beneath the shingles or impervious membrane along with a wire network for aggregating power from these devices and delivering it to a remote location for use. The system then operates as described above to capture solar energy, convert it to electrical energy, and transmit this energy wirelessly to a grid. The system may include connectors on insulation boards for coupling the electrical grids of adjacent boards together or the fasteners used to attach insulation boards to a roof deck may be specially designed to make these connections.

In an alternate embodiment, solar cell arrays may be located on the exposed surface of shingles or an impervious membrane while both wireless resonators and corresponding resonant capture devices are incorporated into the shingles or membrane likely on the bottom side thereof. In such an embodiment, a wired array may be incorporated in the insulation layer below. The resonant capture devices may be electrically connected to the wired array through inductive or capacitive coupling to eliminate holes or other hygrothermal breaks or bypasses. Advantages also include reduced energy losses, elimination of arcing or shorting risks from wiring and plugs, less labor to install, and the requirement of minimal skills such that standard roofing practices can be employed.

Concentrated PV System with Wireless Power Transfer

Photovoltaic systems are known wherein sunlight is captured over a relatively large area and focused or otherwise concentrated onto a smaller area containing solar cells. Such systems are sometimes referred to as concentrated photovoltaic (PV) systems. Concentrated PV systems are applicable to solar roofing and solar shingles, but also are used in solar power systems that are not mounted on a roof but rather may be mounted to appropriate racks and frames on the ground. In any event, advantages of concentrated PV systems include high energy output in a smaller residential or commercial footprint. An aspect of the present invention includes the incorporation of wireless power transfer technology into a concentrated PV system. In one particular embodiment, a system includes a solar cell array and a reflector or lens assembly for concentrating sunlight from an area greater than the footprint of the array onto the solar cells. Because of the significantly greater heat generated at the solar cells, a cooling system is employed to cool the array. The cooling system may include a water filled gutter, air circulation passages, or other structures for removing heat from the solar cell array.

A resonant wireless power coupling system beams energy generated by the solar cell array wirelessly to resonant capture devices as described in detail below. In this case, the resonant capture devices may be incorporated into the structure of the grid or support system or otherwise.

Miscellaneous

As mentioned, the concepts of this invention are applicable to commercial roofing installations. In commercial settings, traditional solar panels may be used on the roof of a building with wireless resonators transmitting power to resonant capture devices on the back or protected side of a commercial roofing membrane. Wireless repeaters protected by the membrane also may be used which then re-transmit power carrying signals to resonant capture devices in remote central locations. The components incorporated into the roofing membrane may be centrally located or located in the selvage only of the membranes.

In another aspect, a solar shingle system includes shingle panels having wireless resonators on one side of the panel with a wireless repeater on the opposite side of the next adjacent panel.

In still another aspect, wireless repeaters are used to “aggregate” power from multiple solar cells and re-transmit the aggregated power to fewer resonant receivers located remotely.

In an additional aspect, electrical energy captured by solar arrays is directed to a ridge vent extending along a ridge of a roof or to an edge of a roof, where a wireless resonator and resonant capture device transfers the energy through the roof deck without the need for penetrations. Junction boxes can be moved to these locations as well.

Throughout the forgoing discussions, the word “shingle” has been used widely to refer to a panel on a roof that bears a solar cell array. However, solar cell arrays may also be carried by panels mounted on a traditional shingled roof or mounted to a membrane covered commercial roof. Therefore, whenever the word “shingle” is used in the forgoing discussion and following aspects in the context of a solar cell array, it should be construed to mean any panel or other structure that can be installed on a roof and carry solar cells for generating electricity from the sun. This includes “solar shingles” that are installed in place of traditional shingle, and also includes more traditional panels that are mounted on residential or commercial roof.

The invention has been described herein in terms of preferred embodiments and methodologies considered to represent the best modes of carrying out the invention. It will be understood by the skilled artisan, however, that a wide variety of additions, deletions, and modifications, both subtle and gross, might well be made without departing from the spirit and scope of the invention.

What is claimed is:

1. A solar collection system for installation on the roof of a structure to convert sunlight to electrical energy and distribute the electrical energy to a remote location, the solar collection system comprising:
an underlayment for installation on an area of the roof to be used for collecting sunlight;
a plurality of resonant devices incorporated into the underlayment in a predetermined pattern;
a plurality of solar collectors configured to be installed in an array on the roof overlying the underlayment;
at least some of the solar collectors carrying a wireless resonator;
the wireless resonators of the solar collectors aligning in a predetermined relationship with the resonant devices of the underlayment when the solar collectors are installed over the underlayment to transfer electrical power generated by the solar collectors to the resonant devices without physical connection.

2. The system of aspect 1 and wherein the solar collectors comprise solar shingles.

3. The system of aspect 1 further comprising inverters associated with each of the solar collectors for converting DC voltage developed by each solar collector to AC voltage that is coupled to the wireless resonator.

4. A solar collection system as recited in aspect 1 wherein the resonant devices incorporated into the underlayment comprise resonant capture devices.

5. A solar collection system as recited in aspect 4 further comprising a wiring grid incorporated into the underlayment electrically connecting the resonant capture devices for delivering electrical power from the resonant capture devices to a remote location.

6. A solar collection system as recited in aspect 5 wherein the wiring grid electrically connects the resonant capture devices in parallel, in series, or in a combination thereof.

7. A solar collection system as recited in aspect 6 and further comprising an electrical bus incorporated into the underlayment, the wiring grid being electrically connected to the electrical bus.

8. A solar collection system as recited in aspect 4 and wherein the resonant capture devices are aligned beneath corresponding solar collectors.

9. A solar collection system as recited in aspect 4 wherein the resonant capture devices are embedded within the material of the underlayment.

10. A solar collection system as recited in aspect 1 wherein the resonant devices comprise wireless repeaters.

11. A solar collection system as recited in aspect 10 further comprising at least one resonant capture device positioned to receive power wirelessly from one or more of the wireless repeaters of the underlayment and to convert the received power to usable electrical power.

12. A solar collection system as recited in aspect 11 wherein the at least one resonant capture device is located remotely from the wireless repeaters.

13. A solar collection system as recited in aspect 11 wherein the wireless repeaters are uniquely identifiable and wherein the system monitors the wireless repeaters and identifies wireless repeaters with signals that indicate a potential fault.

14. A solar collection system as recited in aspect 13 further comprising monitoring components in the one or more resonant capture devices that monitor the wireless repeaters.

15. A solar collection system as recited in aspect 13 further comprising an electrical bus coupled to the at least one resonant capture device for delivering electrical power from the at least one resonant capture device to a remote location.

16. A solar collection system as recited in aspect 1 further comprising electrical inverters associated with the wireless resonators for converting DC voltage established by the solar collectors to AC voltage.

17. A method comprising:
(a) allowing a solar collector on the roof of a building to be exposed to sunlight to establish a voltage;
(b) converting the voltage to a wirelessly transmittable electromagnetic signal;
(c) transmitting the electromagnetic signal wirelessly;
(d) receiving the transmitted electromagnetic signal through a resonant device incorporated into an underlayment beneath the solar collector;
(e) converting the received electromagnetic signal to a voltage; and
(f) conveying the converted voltage to a remote location for use.

18. The method of aspect 17 wherein step (d) comprises receiving the transmitted electromagnetic signal through a resonant capture device.

19. The method of aspect 17 wherein step (d) comprises receiving the transmitted electromagnetic signal through a wireless repeater in the underlayment.

20. The method of aspect 19 and further comprising the step of retransmitting the electromagnetic signal with the wireless repeater to be received and converted to a voltage through a resonant capture device located remotely from the wireless repeater.

21. The method of aspect 20 further comprising the step of inverting the voltage established in step (a) to an AC voltage prior to step (b).

22. A roofing installation comprising a roof deck, an insulating layer above the roof deck, and roofing material above the insulating layer, the roofing material incorporating solar cell arrays and at least a wireless resonator, and components in the insulating layer for receiving signals from the wireless resonators of the roofing material.

23. The roofing installation of aspect 22 wherein the components in the insulating layer comprise resonant capture devices.

24. The roofing installation of aspect 22 wherein the components in the insulation layer comprise wireless repeaters.

25. The roofing installation of aspect 22 further comprising a wiring grid incorporated into the insulation layer.

26. The roofing installation of aspect 22 and further comprising mechanical fasteners holding the roofing material to the roof, at least some of the mechanical fasteners incorporating a wireless power transfer component.

27. The roofing installation of aspect 26 wherein the wireless power transfer component comprises a wireless repeater.
